(19) United States
(12) Patent Application Publication
(10) Pub. No.: US 2016/0285003 A1
(43) Pub. Date: Sep. 29, 2016

(54) MULTILAYER STRUCTURE WITH SBF MATRIX MATERIALS IN ADJACENT LAYERS

(71) Applicant: SOLVAY SA, Brussels (BE)

(72) Inventors: Olivier GAUDIN, Brussels (BE); Jonathan MAUNOURY, Brussels (BE); Enrico ORSELLI, Cologne (DE)

(21) Appl. No.: 15/037,118

(22) PCT Filed: Nov. 17, 2014
(86) PCT No.: PCT/EP2014/074812

§ 371 Date: May 17, 2016

(30) Foreign Application Priority Data
Nov. 17, 2013 (EP) 13193224.6

(51) Int. Cl. H01L 51/00; H01L 51/50

(52) U.S. Cl. CPC H01L 51/0056; H01L 51/5004; H01L 51/5072; H01L 51/5012; H01L 51/0072; H01L 51/0085; H01L 2251/552

(57) ABSTRACT

Multilayer structure suitable for forming part of an organic electronic device, said structure comprising at least two adjacent layers L1 and L2 wherein both layers L and L2 comprise at least 50 wt % of a spirobifluorene derivative or an open spirobifluorene derivative.

The present invention relates to multilayer structures suitable for forming part of an organic electronic device having at least one couple of adjacent layers, each of said layers comprising an organic compound which is derived from substituted or unsubstituted spirobifluorene, substituted or unsubstituted open spirobifluorene, substituted or unsubstituted spirobifluorenyl, substituted or unsubstituted open spirobifluorenyl, substituted or unsubstituted spirobifluorenylene or substituted or unsubstituted open spirobifluorenylene.

Today various organic electronic devices are under active study and development, in particular optoelectronic devices based on electroluminescence (EL) from organic materials.

In contrast to photoluminescence, i.e. the light emission from an active material as a consequence of optical absorption and relaxation by radiative decay of an excited state, electroluminescence (EL) is a non-thermal generation of light resulting from the application of an electric field to a substrate. In this latter case, excitation is accomplished by recombination of charge carriers of contrary signs (electrons and holes) injected into an organic semiconductor in the presence of an external circuit.

A simple prototype of an organic light-emitting diode (OLED), i.e. a single layer OLED, is typically composed of a thin film of an active organic material which is sandwiched between two electrodes, one of which needs to have a degree of transparency sufficient in order to observe light emission from the organic layer.

If an external voltage is applied to the two electrodes, charge carriers, i.e. holes at the anode and electrons at the cathode, are injected to the organic layer beyond a specific threshold voltage depending on the organic material applied. In the presence of an electric field, charge carriers move through the active layer and are non-radiatively discharged when they reach the oppositely charged electrode. However, if a hole and an electron encounter one another while drifting through the organic layer, excited singlet (anti-symmetric) and triplet (symmetric) states, so-called excitons, are formed. For every three triplet excitons that are formed by electrical excitation in an OLED, one singlet exciton is created. Light is thus generated in the organic material from the decay of molecular excited states (or excitons) according to a radiative recombination process known as either fluorescence for which spin symmetry is preserved, or phosphorescence when luminescence from both singlet and triplet excitons can be harvested.

High efficiency OLEDs based on small molecules usually comprise a multiplicity of different layers, each layer being optimized towards achieving the optimum efficiency of the overall device.

Typically such OLEDs comprise a multilayer structure comprising multiple layers serving different purposes. Devices generally referred to as p-i-n OLED comprise typically at least five layers: a p-doped hole transport layer, also referred to as hole injection layer or HIL, an usually undoped electron blocking layer (EBL) (also referred to as hole transporting layer (HTL)), at least one emissive layer (EML), an usually undoped hole blocking layer (HBL), also referred to as electron transporting layer (ETL) and an n-doped electron transport layer, also referred to as electron injecting layer (EIL).

In order to achieve an optimum efficiency, the physical properties of each material for each individual layer of the stack (as e.g. carrier transport properties, HOMO and LUMO levels, triplet levels) have to be selected properly depending on the functionality of the layer.

For OLEDs manufactured by vacuum technologies (deposition from the gas phase) so called homojunction-type OLEDs have been described in the literature. Such devices are characterized by the fact that the number of different matrix materials used for the different layers is lower than the number of layers, i.e. at least two of the layers have the same matrix material. In an ideal homojunction device, all the matrix materials are identical or at least very similar in molecular properties and structure.

Organic electronic devices with two adjacent layers comprising matrix materials with 9,9′-spirobifluorene units have been described in the literature.

US 2010/0331506 in Table 1 describes organic electronic devices with a hole transport layer and an adjacent emissive layer wherein both layers comprise a SBF compound as matrix material. The number of spirobifluorene units in the materials of the adjacent layers differs, which has certain disadvantages.

Similar devices are described in US 2007/0051944 and US 2009/0118453; in all cases the number of spirobifluorene units in the matrix materials of adjacent layers differ which, as mentioned above, has certain disadvantages.

US 2007/0134510 discloses multilayer devices with SBF derivatives as matrix materials for at least two adjacent layers in Table 1 on page 6; the number of SBF units in the compounds in the adjacent layers in a number of the examples is identical; however, the matrix materials differ significantly in the HOMO and LUMO level which is detrimental for the overall performance of the device.

US 2013/0207046 (corresponding to DE 10 2010 045405) relates to materials for electroluminescent devices. Amongst these materials a variety of compounds is described which comprise one SBF unit of formula (1) as hereinafter defined. All the compounds disclosed comprise one SBF unit, i.e. there are no compounds with more than one SBF unit disclosed, which are connected through a linker. In Working Example E starting on page 93 the manufacture of OLEDs is disclosed using the SBF compounds described in the document in various layers. The set-up of the devices is shown in Table 1 starting on page 94 of the document and amongst the devices manufactured there are some examples wherein a SBF compound with one SBF unit is contained in more than one layer and in some cases in two adjacent layers. Some of the devices shown in Table 1 comprise an SBF compound in the emissive layer and in an adjacent layer or two SBF compounds in the emissive layer and one SBF compound in an adjacent layer. In the latter case, the HOMO and LUMO level of the two compounds differ by more than 0.2 eV.

The devices described in the prior art which comprise SBF derivatives as matrix materials in at least two adjacent layers are not fully satisfactory in terms of efficiency and lifetime and thus it is desirable to provide improved devices on the basis of SBF compounds (which have certain advantages when used as matrix materials in organic electronic devices), which was an object of the present invention.

This object has been achieved in accordance with the present invention with the multilayer structures as defined in claims 1 and 2.

Preferred embodiments of the present invention are set forth in the dependent claims and the detailed description hereinafter.

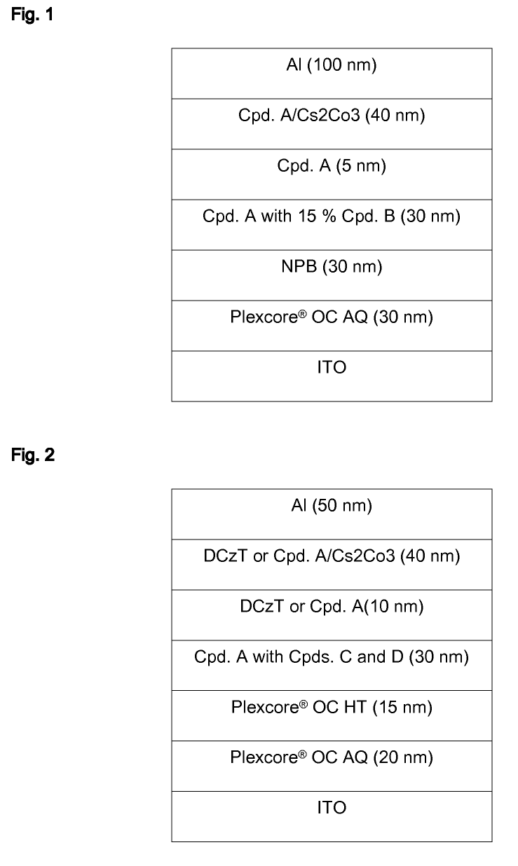

FIG. 1 shows the device structure of the devices in accordance with Example 1 and Comparative Example 1.

FIG. 2 shows the device structure of the devices in accordance with Example 2 and Comparative Example 2.

In accordance with a first embodiment of the present invention, the multilayer structures in accordance with the present invention comprise at least one couple of layers L1 and L2 which are adjacent to each other, wherein

a) said layer L1 of the multilayer structure is an emissive layer and comprises at least 50 wt %, preferably at least 60 wt %, at least 70 wt %, at least 80 wt %, at least 90 wt %, at least 92 wt %, at least 94 wt %, at least 96 wt % or at least 98 wt %, based on the total weight of L1, of a compound C1 selected from the group consisting of compounds of the formula SBF and

b) said layer L2 of the multilayer structure comprises at least 50 wt %, preferably at least 60 wt %, at least 70 wt %, at least 80 wt %, at least 90 wt %, at least 92 wt %, at least 94 wt %, at least 96 wt % or at least 98 wt %, based on the total weight of L2, of a compound C2, which may be the same or different from C1, selected from the group consisting of compounds of the formula SBF, wherein the HOMO and LUMO levels of the compounds C1 and C2 are the same as, or differ by at most 0.2 eV from, respectively, the HOMO and LUMO levels of the organic compound C2.

In accordance with a second embodiment, the multilayer structures in accordance with the present invention comprise at least one couple of layers L1 and L2 which are adjacent to each other, wherein

a) said layer L1 of the multilayer structure comprises at least 50 wt %, preferably at least 60 wt %, at least 70 wt %, at least 80 wt %, at least 90 wt %, at least 92 wt %, at least 94 wt %, at least 96 wt % or at least 98 wt %, based on the total weight of L1, of a compound C1 selected from the group consisting of compounds of the formulae SBF′-Lnk-SBF′ or SBF′-Lnk-(-SBF″-Lnk′-)ₙ-SBF′ and

b) said layer L2 of the multilayer structure comprises at least 50 wt %, preferably at least 60 wt %, at least 70 wt %, at least 80 wt %, at least 90 wt %, at least 92 wt %, at least 94 wt %, at least 96 wt % or at least 98 wt %, based on the total weight of L2, of a compound C2, which may be the same or different from C1, selected from the group consisting of compounds of the formulae SBF′-Lnk-SBF′ or SBF′-Lnk-(-SBF″-Lnk′-)ₙ-SBF′,

wherein n in the formula SBF′-Lnk-(-SBF″-Lnk′-)ₙ-SBF′ is an integer of from 1 to 9, preferably of from 1 to 6 and particularly preferably of from 1 to 4, and wherein the HOMO and LUMO levels of the compounds C1 and C2 are the same as, or differ by at most 0.2 eV from, respectively, the HOMO and LUMO levels of the organic compound C2.

Especially preferred n in compounds of formula

SBF′-Lnk-(-SBF″-Lnk′-)ₙ-SBF′ is 1.

SBF, which may be the same or different at each occurrence, in accordance with the present invention represents a substituted or unsubstituted spirobifluorene of formula (1) or a substituted or unsubstituted open spirobifluorene of formula (2),

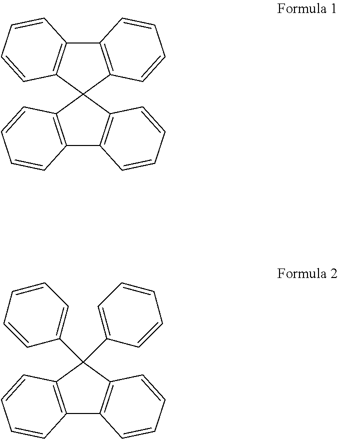

SBF′, which may be the same or different at each occurrence, in accordance with the present invention represents a substituted or unsubstituted spirobifluorenyl of formula (1′) or a substituted or unsubstituted open spirobifluorenyl of formula (2′),

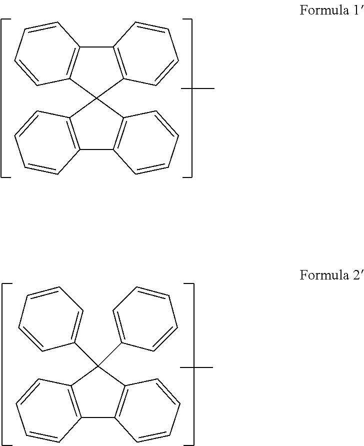

SBF″, which may be the same or different at each occurrence, represents a substituted or unsubstituted spirobifluorenylene of formula (1″) or a substituted or unsubstituted open spirobifluorenylene of formula (2″)

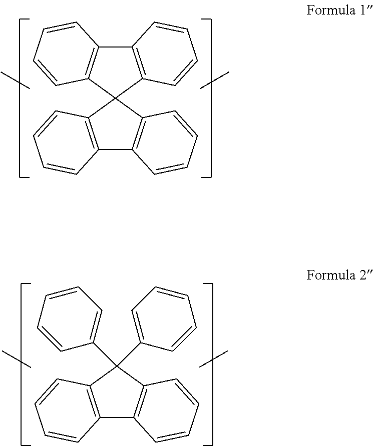

wherein the solid lines represent the bonds to the linker Lnk respectively Lnk′ and Lnk and Lnk′ may be attached to any position of any of the aromatic rings.

In accordance with the present invention compound C1 and compound C2 comprise the same total number of units chosen from SBF, SBF′ and SBF″ units and the HOMO and LUMO levels of the compounds C1 and C2 are the same as, or differ by at most 0.2 eV from, respectively, the HOMO and LUMO levels of the organic compound C2.

The HOMO and LUMO levels of the organic molecules used in the process of the present invention are determined from cyclic voltammetry measurements in solution as follows:

The measurements are performed at room temperature, under inert atmosphere, with a conventional three-electrode configuration, the solution being outgassed before use with a stream of argon for 5-10 min. The three-electrode cell may consist e.g. of a glassy carbon disk as working electrode, a Pt wire or a Pt rod as a counter electrode and a Pt wire or a carbon rod as pseudo-reference electrode. Ferrocene is used as an internal reference. Other cell configurations may also be used. The solvents used for the determination of the HOMO and LUMO levels are respectively anhydrous dichloromethane and anhydrous tetrahydrofuran, the supporting electrolyte is 0.1 M tetrabutylammonium hexafluorophosphate and the host concentrations are 2-0.5 millimolar. The scan rate is fixed to 100 my/s.

The HOMO levels (E_{HOMO}) of the organic molecules used in the process of the present invention are calculated from the measured half wave potential of their first oxidation wave (E_{1 ox 1/2}) using the following equation:

E_{HOMO}−(−4.8)=−[E_{1 ox 1/2}−E_{ox 1/2}(FC/Fc⁺)]

wherein the ferrocene HOMO level value has been taken equal to −4.8 eV below the vacuum level according to Pommerehene and al. Adv. Mater. 7(6), 551-554 (1995) and wherein E_{ox 1/2}(Fc/Fc⁺) corresponds to the measured half wave potential of the ferrocene oxidation wave. For irreversible systems, E_{pa 1} peak potential value of the first oxidation wave is used instead of the half wave potential E_{1ox 1/2}.

The LUMO levels (E_{LUMO}) of the organic molecules used in the process of the present invention are calculated from the measured half wave potential of their first reduction wave (E_{1ox 1/2}) using the following equation:

E_{LUMO}−(−4.8)=−[E_{1 red 1/2}−E_{ox 1/2}(FC/FC⁺)]

wherein the ferrocene HOMO level value has been taken equal to −4.8 eV below the vacuum level according to Pommerehene et al. Adv. Mater. 7(6), 551-554 (1995) and wherein E_{ox 1/2}(Fc/Fc⁺) corresponds to the measured half wave potential of the ferrocene oxidation wave. For irreversible systems, E_{pc 1} peak potential value of the first reduction wave is used instead of the half wave potential E_{1 red 1/2}.

The substituents in substituted formulae SBF, SBF′ or SBF″ may be preferably selected from halogen, amino or C₁-C₃₀ hydrocarbyl or C₁-C₃₀ heterohydrocarbyl groups. Examples for C₁-C₃₀ hydrocarbyl or C₁-C₃₀ heterohydrocarbyl groups are alkyl, alkoxy, substituted amino, cyano, alkenyl, alkynyl, arylalkyl, aryl and heteroaryl groups. Preferred are respective groups with 1 to 20 and in particular with 1 to 8 carbon atoms. Two substituents may also form an annealed ring system with other rings selected from cycloalkyl, aryl and heteroaryl rings.

Preferred aryl groups comprise 5 to 30 carbon atoms, more preferably form 6 to 14 carbon atoms.

Exemplary heteroaryl rings are preferably derived from the heteroarenes group consisting of 2H-pyrrole, 3H-pyrrole, 1H-imidazole, 2H-imidazole, 4H-imidazole, 1H-1,2,3-triazole, 2H-1,2,3-triazole, 1H-1,2,4-triazole, 1H-pyrazole, 1H-1,2,3,4-tetrazole, imidazol-2-ylidene, oxazole, isoxazole, thiazole, isothiazole, 1,2,3-oxadiazole, 1,2,5-oxadiazole, 1,2,3-thiadiazole and 1,2,5-thiadiazole rings.

In accordance with a first preferred embodiment of the present invention, compounds C1 and C2 are selected from compounds of formula SBF as defined above. These compounds may be substituted or unsubstituted as outlined above.

In accordance with another preferred embodiment of the present invention, compounds C1 and C2 are selected from compounds of formula SBF′-Lnk-SBF′ or SBF′-Lnk-(-SBF″-Lnk′-)ₙ-SBF′ with at least one of the SBF′ and SBF″ having at least one substituent other than hydrogen as defined above.

Lnk and Lnk′, which may be the same or different at each occurrence, are preferably a single bond, a C₁ to C₃₀ hydrocarbylene or a C₁ to C₃₀ heterohydrocarbylene group.

Particularly preferred examples for Lnk and Lnk′ are selected from divalent residues of biphenyl or triphenyl or a divalent residue of the following formulae (3) to (10)

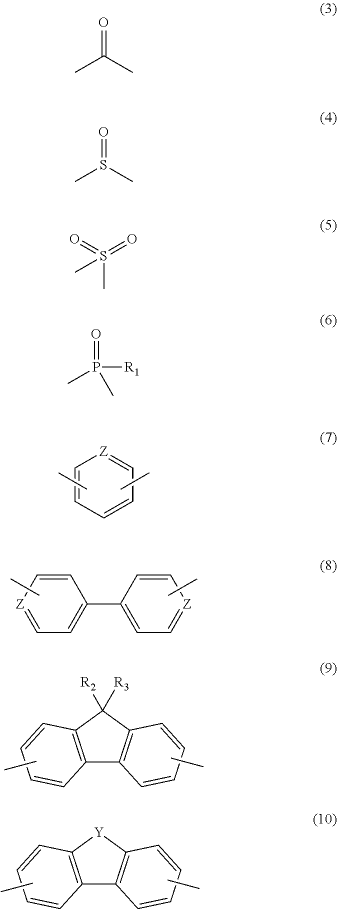

wherein Z is selected from C, N, O or S, Y is N—R₄, O, S or SiR₅R₆, wherein R₁ is selected from C₁-C₂₀ hydrocarbyl or C₁-C₂₀ heterohydrocarbyl, R₂ and R₃ are independently selected from hydrogen or C₁-C₂₀ alkyl, and R₄, R₅ and R₆ are independently selected from C₁-C₂₀ hydrocarbyl or C₁-C₂₀ heterohydrocarbyl, preferably from C₁-C₂₀ alkyl or C₁-C₂₀ aryl.

In accordance with still another preferred embodiment of the present invention the multilayer structure comprises identical compounds C1 and C2.

In accordance with yet another preferred embodiment of the present invention, SBF is selected from compounds of formulae

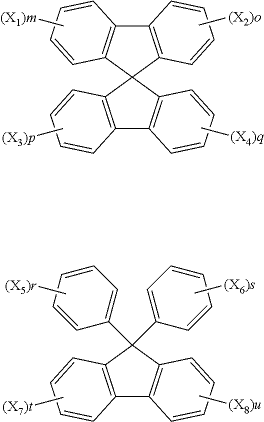

wherein X₁ to X₈ are independently selected from substituents other than hydrogen and m, o, p, q, r, s, t and u, independently of one another represent an integer of from 0 to 4.

Preferred substituents X₁ to X₈ are C₁-C₃₀ hydrocarbyl- or C₁-C₃₀ heterohydrocarbyl groups as defined before.

Multilayer structures wherein compounds C1 and C2 are selected from the following formulae are particularly preferred:

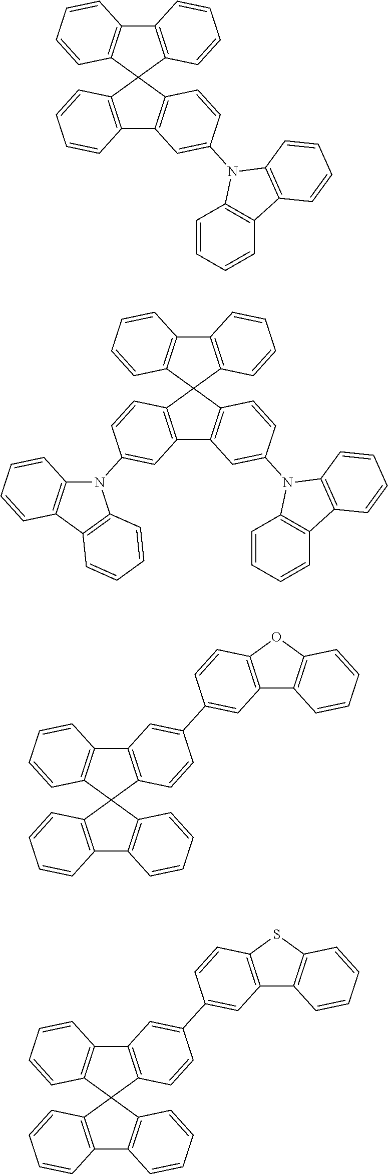

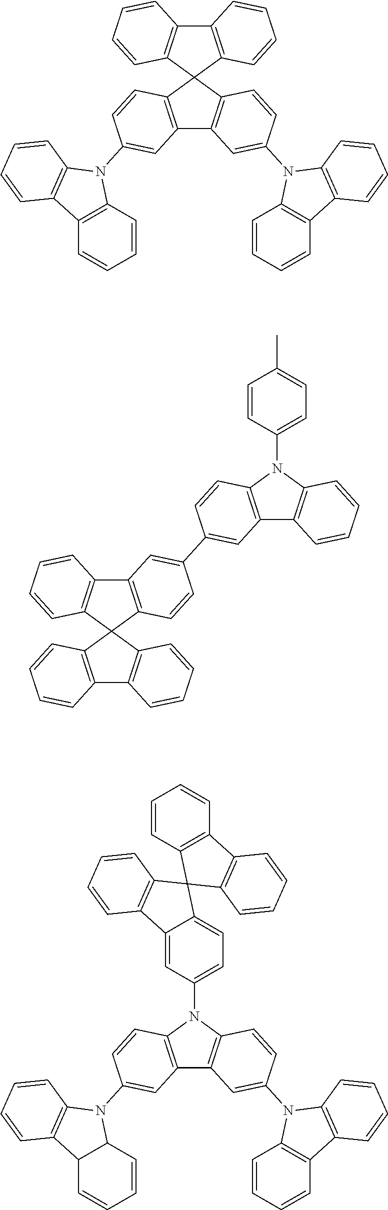 [SMILES: c1ccc2c(c1)-c1ccccc1C21c2ccc(-n3c4ccccc4c4ccccc43)cc2-c2cc(-n3c4ccccc4c4ccccc43)ccc21 ; Cc1ccc(-n2c3ccccc3c3cc(-c4ccc5c(c4)-c4ccccc4C54c5ccccc5-c5ccccc54)ccc32)cc1 ; C1=CC2c3ccccc3N(c3ccc4c(c3)c3cc(-n5c6ccccc6c6ccccc65)ccc3n4-c3ccc4c(c3)-c3ccccc3C43c4ccccc4-c4ccccc43)C2C=C1]

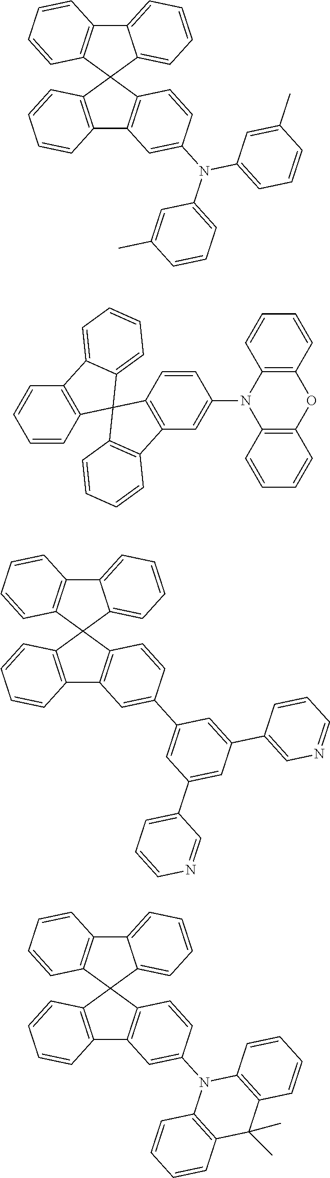

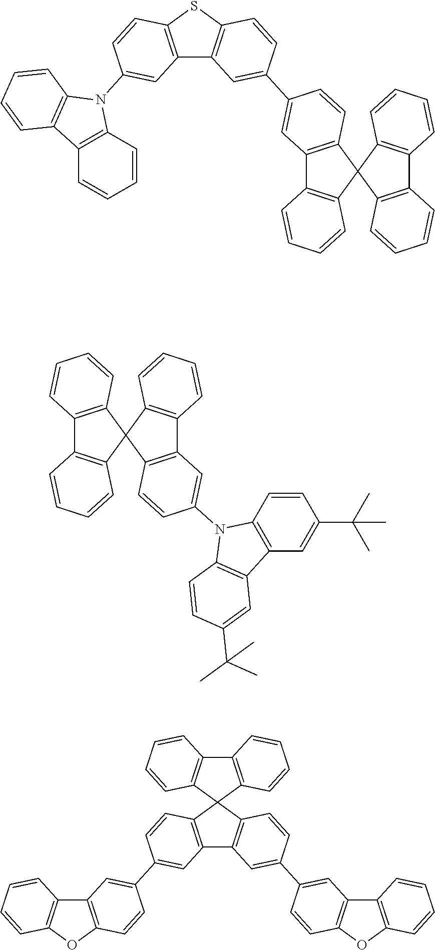 [SMILES: c1ccc2c(c1)-c1ccccc1C21c2ccccc2-c2cc(-c3ccc4sc5ccc(-n6c7ccccc7c7ccccc76)cc5c4c3)ccc21 ; CC(C)(C)c1ccc2c(c1)c1cc(C(C)(C)C)ccc1n2-c1ccc2c(c1)-c1ccccc1C21c2ccccc2-c2ccccc21 ; c1ccc2c(c1)-c1ccccc1C21c2ccc(-c3ccc4oc5ccccc5c4c3)cc2-c2cc(-c3ccc4oc5ccccc5c4c3)ccc21]

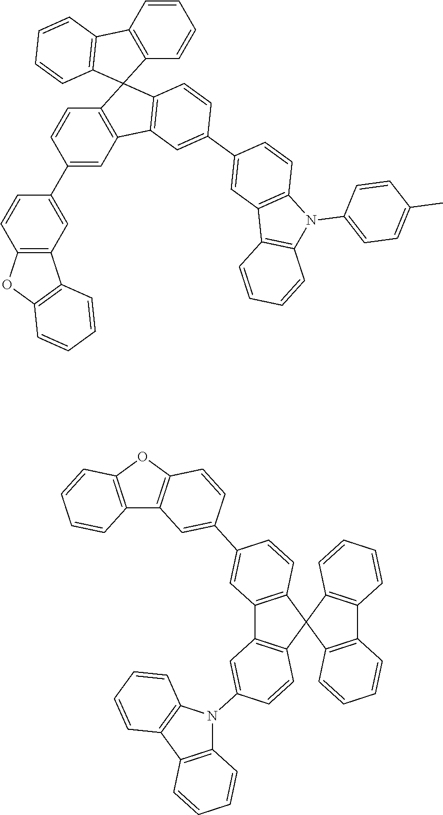 [SMILES: Cc1ccc(-n2c3ccccc3c3cc(-c4ccc5c(c4)-c4cc(-c6ccc7oc8ccccc8c7c6)ccc4C54c5ccccc5-c5ccccc54)ccc32)cc1 ; c1ccc2c(c1)-c1ccccc1C21c2ccc(-c3ccc4oc5ccccc5c4c3)cc2-c2cc(-n3c4ccccc4c4ccccc43)ccc21]

In still another preferred embodiment compounds C1 and C2 are independently selected from

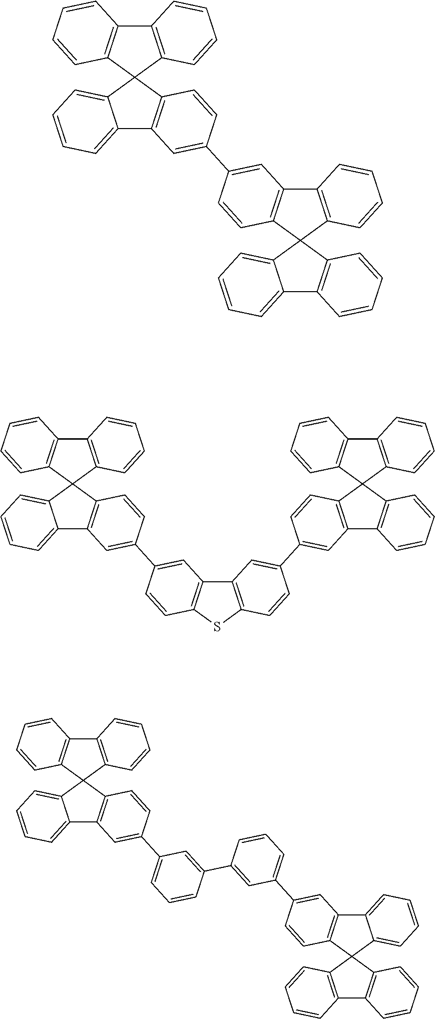

Another preferred embodiment of the present invention relates to multilayer structures comprising at least one triplet of layers L1, L2 and L3, wherein layers L1 and L2 are as specified above, wherein layers L2 and L3 are adjacent to each other, and wherein said layer L3 comprises at least 50 wt %, based on the total weight of L3, of a compound C3 which may be the same or different from C1 and C2, selected from the group consisting of compounds of the formulae SBF, SBF′-Lnk-SBF′ or SBF′-Lnk-(-SBF″-Lnk′-)ₙ-SBF, wherein n is an integer of from 1 to 9.

Preferred examples for compounds C3 are selected from the preferred examples for C1 and C2 as described hereinbefore.

Especially preferably, at least two of C1, C2 and C3, even more preferably C1, C2 and C3 in this embodiment are identical.

Another preferred embodiment of the present invention relates to a multilayer structure as described before, said structure comprising at least one quadruplet of layers L1, L2, L3 and L4 wherein layers L3 and L4 are adjacent to each other, and wherein said layer L4 comprises at least 50 wt %, based on the total weight of L4, of a compound C4 which may be the same or different from C1, C2 or C3, selected from the group consisting of compounds of the formulae SBF, SBF′-Lnk-SBF′ or SBF′-Lnk-(-SBF″-Lnk′-)ₙ-SBF, wherein n is an integer of from 1 to 9.

Preferred examples for compounds C4 are selected from the preferred examples for C1, C2 and C3 as described above.

Especially preferably, C1, C2, C3 and C4 in this embodiment are identical.

Still another preferred embodiment of the present invention relates to a multilayer structure as described above, said structure comprising at least one quintuplet of layers L1, L2, L3, L4 and L5 wherein layers L4 and L5 are adjacent to each other, and wherein said layer L5 comprises at least 50 wt %, based on the total weight of L5, of a compound C5 which may be the same or different from C1, C2, C3 or C4, selected from the group consisting of compounds of the formulae SBF, SBF′-Lnk-SBF′ or SBF′-Lnk-(-SBF″-Lnk′-)ₙ-SBF, wherein n is an integer of from 1 to 9.

Preferred examples for compounds C5 are selected from the preferred examples for C1, C2, C3 and C4 as described above.

Especially preferably, two of C1, C2, C3, C4 and C5 in this embodiment are identical, even more preferably three of C1, C2, C3, C4 and C5, still more preferably four of C1, C2, C3, C4 and C5 and most preferably all of C1, C2, C3, C4 and C5 in this embodiment are identical.

In the embodiments described hereinabove with more than two adjacent layers comprising a spirobifluorene compound, i.e. where compounds C1, C2 and C3 or compounds C1, C2, C3 and C4 or compounds C1, C2, C3, C4 and C5 are present, all these compounds preferably have an identical HOMO or LUMO level or the HOMO and LUMO levels of the compounds differ by at most 0.2 eV, as measured by cyclic voltammetry in solution.

Furthermore, in accordance with a preferred embodiment of the present invention, compounds C1 and C2 and, if present, compounds C3, C4 and C5 constitute at least 60, more preferably at least 70, even more preferably at least 80 and most preferably more than 90 wt % of the entire weight of the respective layer in which they are present. Especially preferably the compounds C1, C2 and, if present, compounds C3, C4 and C5 constitute at least 92 wt %, at least 94 wt %, at least 96 wt % and most preferably at least 98 wt % of the entire weight of the respective layer in which they are present.

A preferred process for the manufacture of a multilayer structure in accordance with the present invention comprises the steps of
a. depositing a first layer L1 of the multilayer structure onto a substrate out of a liquid composition LC1 comprising a solvent system S1 which solvent system S1 contains at least one organic compound C1 wherein the substrate is a previously deposited layer L0 of the multilayer structure or is an element suitable for forming the cathode or the anode of the organic electronic device,
b. thereafter chemically modifying the first layer L1 to reduce its solubility, as measured at room temperature (23° C.) and atmospheric pressure (101.325 kPa), in a solvent system S2 which is identical to or different from solvent system S1, by at least 50%, based on the solubility of the first layer L1 in the solvent system S2 before modification and
c. thereafter depositing a second layer L2 of the multilayer structure onto the first layer L1 out of a liquid composition LC2 comprising the solvent system S2, which solvent system comprises at least one organic compound C2,
   wherein the HOMO and LUMO levels of the organic compound C1 are the same as, or differ by at most 0.2 eV from, respectively, the HOMO and LUMO levels of the organic compound C2.

The concentration of the organic compounds C1 and C2 in the solvent systems S1 and S2 (which may be the same or different) is not particularly critical. In many cases compounds C1 and C2 will be present in a concentration in the range of from 0.05 to 20, preferably from 0.1 to 10 and even more preferably of from 0.2 to 5 wt %, based on the combined weight of solvent system and organic compound. The maximum concentration of the organic compound in the solvent system is often defined by the solubility of the organic compound in the solvent system; it is generally preferred to use the organic compounds C1 and C2 in a concentration not exceeding the solubility in the respective solvent system to avoid having part of the organic compound as solid particles in the solvent system as these solid particles may detrimentally influence the processability through solvent based processing techniques.

The solvent compositions comprise one or more solvents which are selected to achieve a sufficient solubility of the organic compounds C1 and C2 in the respective solvent systems as this is advantageous for forming a homogenous thin layer.

Accordingly, the solvent or solvents in the solvent composition will be selected depending on the chemical structure and properties of organic compounds C1 and C2 selected for the specific project.

Generally, organic solvents will be used in the solvent composition. Although halogenated solvents like fluorinated hydrocarbons are in principle suitable in the process of the present invention, it is preferred to use solvents that are essentially free or entirely free of halogen atoms for safety and environmental reasons. Just by way of example, liquid alkanes, cycloalkanes, aldehydes, ketones, esters, ether or aromatic solvents may be mentioned. In certain deposition methods it may be preferable to use solvent mixtures to adjust the properties of the solvent system to achieve a homogenous thin layer in the deposition process. In this regard it has been shown to be advantageous in certain cases to use solvent mixtures comprising solvents with different boiling temperatures which on one hand provide smooth layers and on the other hand have an evaporation behaviour avoiding premature drying of the solvent composition during deposition which might be detrimental for the efficiency of the multilayer structure. Just by way of example, it may be mentioned here to use solvent combinations comprising a solvent with a boiling point at room temperature of at most 130° C. with a solvent having a boiling point above that limit and preferably having a boiling point of at least 150° C., particularly preferably of at least 180° C. All boiling points refer to the boiling points at atmospheric pressure.

The solvent compositions, in addition to one or more solvents and the organic molecules may also contain further additives and processing aids commonly used in such compositions in solution based processes. These are commercially available and described in the literature and thus no further details are necessary here.

The multilayer structures in accordance with the present invention may also be obtained by vapour deposition methods of subsequent layers.

The skilled person is also aware of suitable methods for the synthesis of compounds C1, C2 and C3 and will select an appropriate method based on his professional experience and the individual target compound. To a certain degree, these compounds are also commercially available. Accordingly, detailed information in this regard are not necessary here.

The multilayer structures in accordance with the present invention are suitable for forming part of an organic electronic device, in particular for forming part of organic light-emitting diodes (OLEDs).

An OLED generally comprises:

a substrate, for example (but not limited to) glass, plastic, metal;

an anode, generally a transparent anode;

a hole injection layer (HIL);

a hole transporting layer (HTL);

an emissive layer (EML);

an electron transporting layer (ETL);

an electron injection layer (EIL) and

a cathode, generally a metallic cathode.

The principal structural elements of an organic light emitting diode have been described in the literature and are known to the skilled person, who will select the appropriate method of manufacture based on the individual needs in the specific case using professional experience.

Preferred organic electronic devices comprise an electron injection layer and an electron transport layer, wherein layer L1 of the multi-layered structure in accordance with the present invention is the electron injection layer and layer L2 is the electron transport layer.

Another group of preferred organic electronic devices comprises an electron transport layer and an emissive layer, wherein layer L1 is the emissive layer and layer L2 is the electron transport layer.

Still another group of preferred organic electronic devices, in particular organic light emitting diodes comprise a triplet of layers as defined above wherein layer L1 is an electron injection layer, layer L2 is an electron transport layer and layer L3 is an emissive layer.

A further preferred group of organic electronic devices, in particular organic light emitting diodes, comprise a quadruplet of layers comprising an electron injection layer, an electron transport layer, an emissive layer and a hole transporting layer, wherein layer L1 is the electron injection layer, layer L2 is the electron transport layer, layer L3 is the emissive layer and layer L4 is the hole transporting layer.

A still further preferred group of organic electronic devices, in particular organic light emitting diodes, comprises a quintuplet of layers comprising an electron injection layer, an electron transport layer, an emissive layer, a hole transporting layer and a hole injection layer, wherein layer L1 is the electron injection layer, layer L2 is the electron transport layer, layer L3 is the emissive layer, layer L4 is the hole transporting layer and layer L5 is the hole injection layer.

### EXAMPLES

All device examples were fabricated by high vacuum thermal evaporation, except for the hole injecting layer which was deposited by the spin-coating technique, and the hole transporting layer of Example 2, also deposited by the spin coating technique. The anode electrode was 120 nm of indium tin oxide (ITO). All devices were encapsulated with a glass lid sealed with an epoxy resin in a nitrogen glovebox (<1 ppm of H₂O and 02) immediately after fabrication, and a moisture getter was incorporated inside the package. The devices were characterized optically and electrically with a C9920-12 External Quantum Efficiency Measurement System from HAMAMATSU Photonics. EQE refers to external quantum efficiency expressed in %, while operational stability tests were done by driving the devices at continuous current at room temperature. LT₅₀ is a measure of lifetime and corresponds to the time for light output to decrease by 50% of the initial value, when the device is driven at a constant current.

### Example 1

The OLED stack consisted of sequentially, from the ITO surface, 30 nm of Plexcore® OC AQ (a self-doping polymer poly(thiophene-3-[2[(2-methoxyethoxy)ethoxy]-2,5-diyl), supplied by Plextronics Inc.) deposited by spin-coating and dried on a hot plate under inert atmosphere at 180° C. for 20 min. On top of the HIL, 30 nm of NPB were deposited by vacuum-thermal evaporation as hole transporting layer (HTL).

Then a 30 nm layer of mCBP (Comparative Example) or Compound A doped with 15% of Compound B was deposited by vacuum-thermal evaporation as the emissive layer (EML). Then a 5 nm layer of mCBP (Comparative Example) or Compound A was deposited by vacuum-thermal evaporation as the hole blocking layer (HBL), also referred to as electron transporting layer (ETL). Then, a 40 nm layer of mCBP (Comparative Example) or Compound A was co-deposited with Cs₂CO₃ by vacuum-thermal evaporation as the electron injecting layer (EIL). The cathode consisted of 100 nm of Aluminum.

NPB, mCBP, Compound A and Compound B have the following structures:

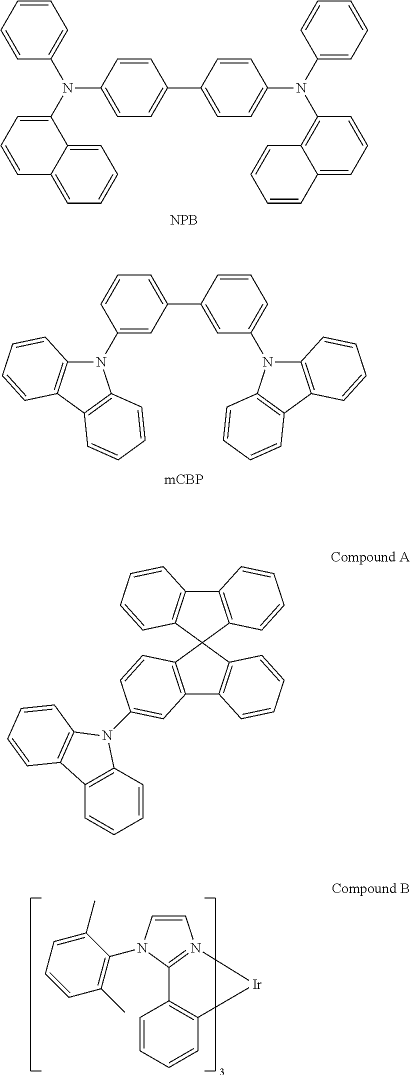

The device structure is summarized in FIG. 1 while Table 1 shows the results measured at 1000 cd/m² for the fabricated devices.

TABLE 1

| Examples | Layer mat. | V | EQE | lm/W | X | Y | Von |
|---|---|---|---|---|---|---|---|
| Comparative | mCBP | 4.9 | 7.7 | 12.9 | 0.23 | 0.45 | 2.8 |
| Ex. 1 | | | | | | | |
| Ex. 1 | Compound A | 3.9 | 7.5 | 16.1 | 0.23 | 0.46 | 2.7 |

As can be seen from Device Example 1, the device with Compound A has comparable external quantum efficiency (EQE) and CIE color coordinates X and Y compared to mCBP of Comparative Example 1, while the operating voltage (V) was substantially reduced and the power efficiency increased from 12.9 to 16.1 lm/W.

### Example 2

The OLED stack, as shown in FIG. 2, consisted of sequentially, from the ITO surface, 20 nm of Plexcore® OC AQ (a self-doping polymer poly(thiophene-3-[2[(2-methoxyethoxy)ethoxy]-2,5-diyl), supplied by Plextronics Inc.) deposited by spin-coating and dried on a hot plate at 180° C. for 20 min. On top of this HIL, 15 nm of Plexcore® OC HT were deposited by spin coating as hole transporting layer (HTL) and baked on a hot plate under inert atmosphere at 180° C. for 30 min.

Then a 30 nm layer of Compound A doped with Compounds C and D was deposited by vacuum-thermal evaporation as the emissive layer (EML). Then a 10 nm layer of DCzT (Comparative Example) or Compound A was deposited by vacuum-thermal evaporation as the hole blocking layer (HBL), also referred to as electron transporting layer (ETL). Then, a 40 nm layer of DCzT (Comparative Example) or Compound A was co-deposited with Cs₂CO₃ by vacuum-thermal evaporation as the electron injecting layer (EIL). The cathode consisted of 50 nm of Aluminum.

Compound A has the structure given in Example 1 and DCzT has the following structure:

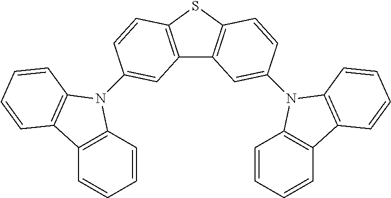 [SMILES: c1ccc2c(c1)c1ccccc1n2-c1ccc2sc3ccc(-n4c5ccccc5c5ccccc54)cc3c2c1]

### DCzT: 2,8-di(9H-carbazol-9-yl)dibenzo[b,d]thiophene

Compounds C and D are respectively blue and red, Ir-based phosphorescent emitters which can be chosen from, but are not limited to, the examples shown in Table 2. In addition, any combination of red, green and blue phosphorescent emitters, or one of them on its own, chosen from, but not limited to, the examples shown in Table 2 could also be used as suitable EML dopants.

The performance data are given in Table 3 and show that the performance of the device in accordance with the present invention is superior to the comparative device. The external quantum efficiency (EQE) increases from 11 to 12.1% and power efficacy from 23.8 to 25.9 lm/W.

The relative lifetime at half initial brightness (LT50rel) measured from 1000 cd/m² increases from 54 to 100 h, i.e. nearly doubles.

In Table 3 J and V are the current density and voltage at a luminance of 1000 cd/m². LT 50rel provides the relative lifetime at half initial brightness, the lifetime of the device in accordance with the present invention being set to 100.

TABLE 2
Blue dopants

| | |
|---|---|
| 1 | 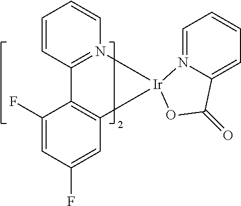 |
| 2 | 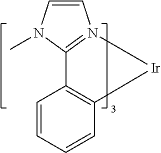 |
| 3 | 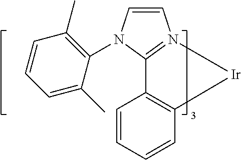 |
| 4 | 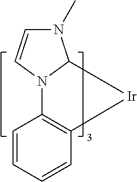 |
| 5 | 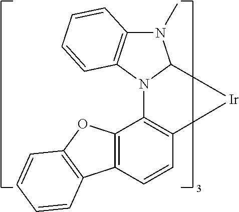 |
| 6 | 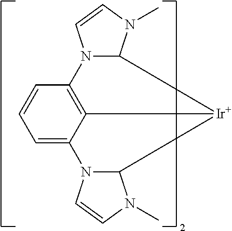 |
| 7 | 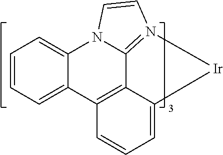 |
| 8 | 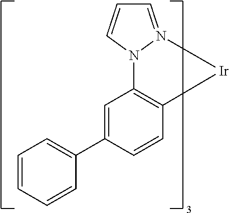 |
| 9 | 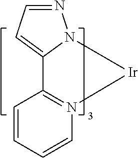 |
| 10 | 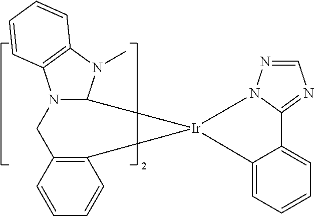 |
| 11 | 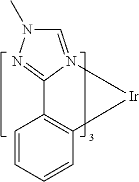 |
| 12 | 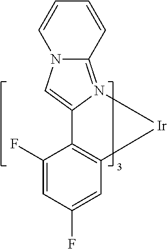 |
| 13 | 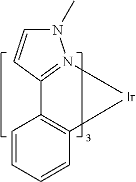 |
| 14 | 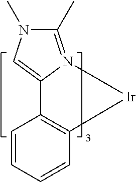 |
| 15 | 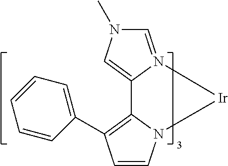 |
| 16 | 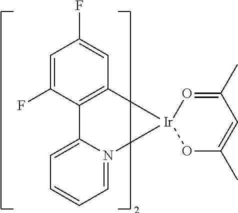 |
| 17 | 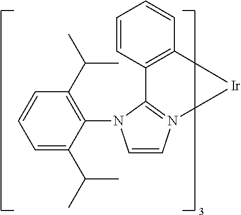 |
| 18 | 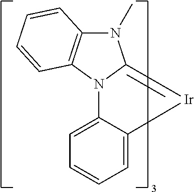 |
| 19 | 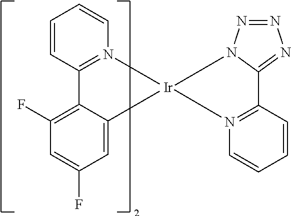 |
| 20 | 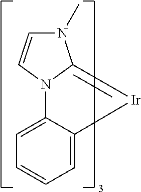 |
| 21 | 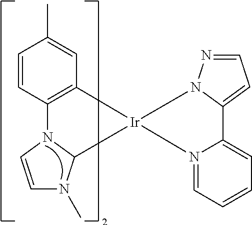 |
| 22 | 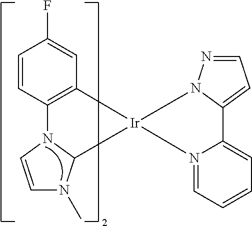 |
| 23 | 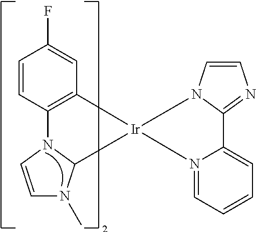 |

Green dopants

| | |
|---|---|
| 24 | 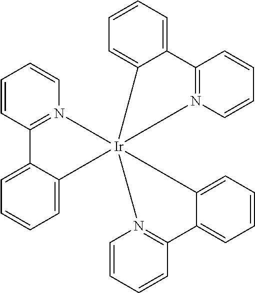 |
| 25 | 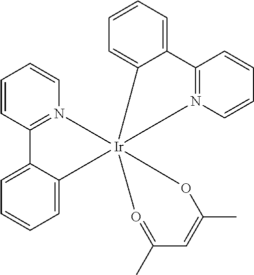 |
| 26 | 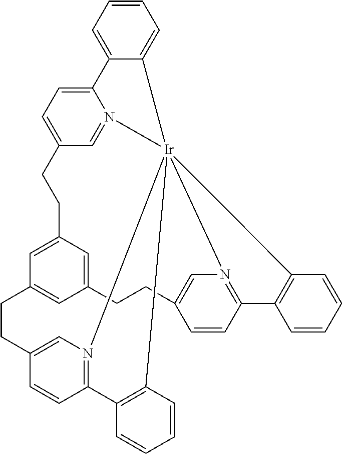 |
| 27 | 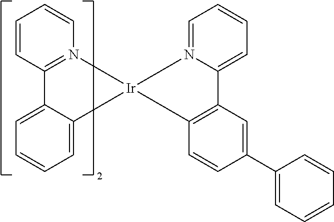 |
| 28 | 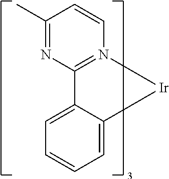 |
| 29 | 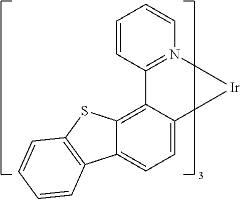 |
| 30 | 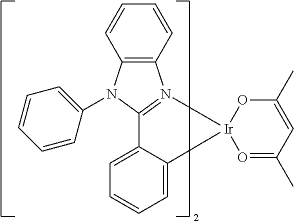 |
| 31 | 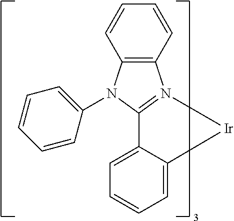 |
| 32 | 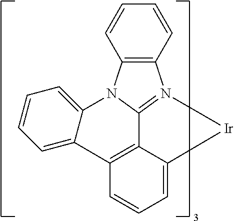 |
| 33 | 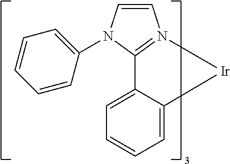 |
| 34 | 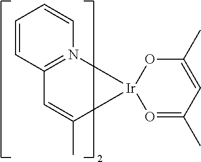 |
| 35 | 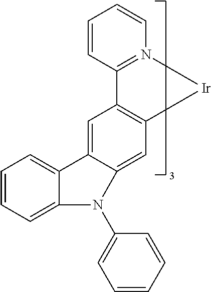 |
| 36 | 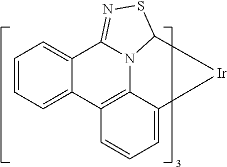 |
| 37 | 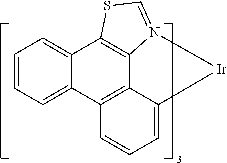 |
| 38 | 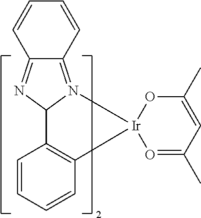 |
| 39 | 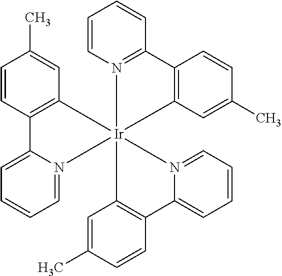 |
| 40 | 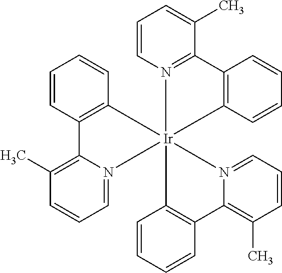 |
| 41 | 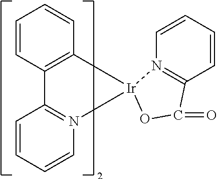 |

Red dopants

| | |
|---|---|
| 42 | 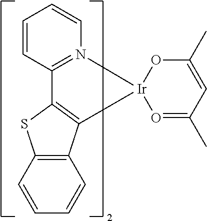 |
| 43 | 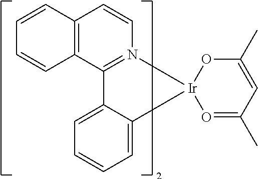 |
| 44 | 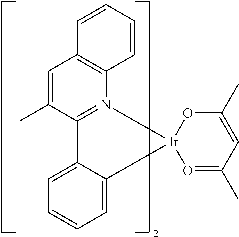 |
| 45 | 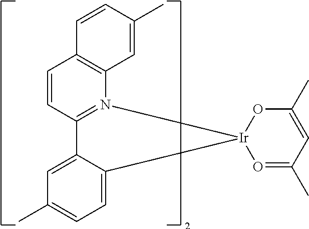 |
| 46 | 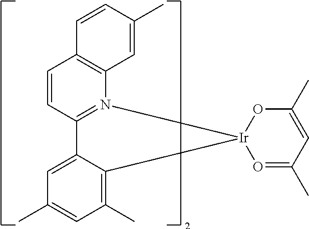 |
| 47 | 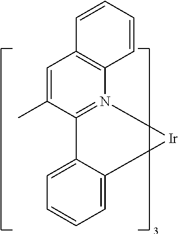 |
| 48 | 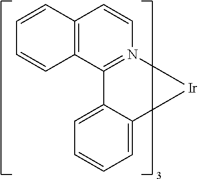 |
| 49 | 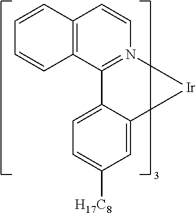 |
| 50 | 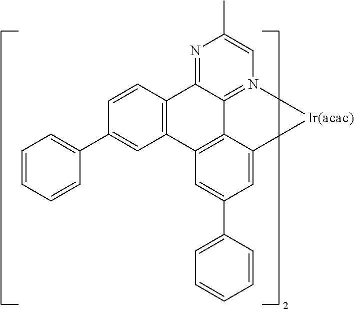 |
| 51 | 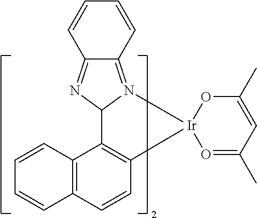 |
| 52 | 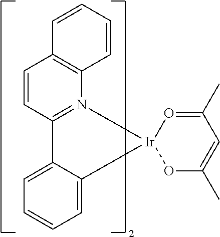 |
| 53 | 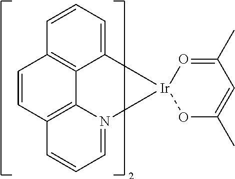 |
| 54 | 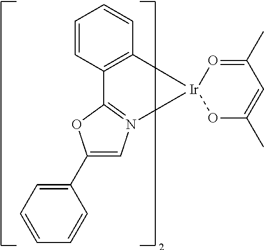 |
| 55 | 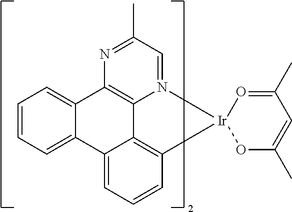 |
| 56 | 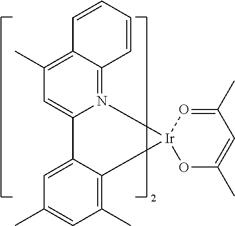 |
| 57 | 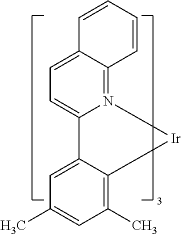 |
| 58 | 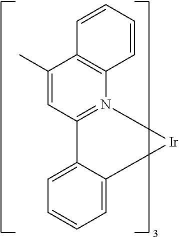 |
| 59 | 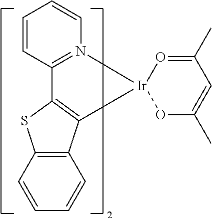 |
| 60 | 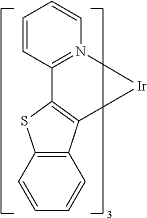 |

TABLE 3

| | | 1000 cd/m² | | | | | | | | From 1000 cd/m² |
|---|---|---|---|---|---|---|---|---|---|---|
| Example | ETL | V | J | EQE | (lm/W) | cd/A | X | Y | Vₒₙ | LT50 rel. |
| 2 | Cpd. A | 3.9 | 3.1 | 12.1 | 25.9 | 32.1 | 0.45 | 0.46 | 2.6 | 100 |
| Comp. 2 | DCzT | 3.9 | 3.4 | 11.0 | 23.8 | 29.2 | 0.44 | 0.46 | 2.6 | 54 |

1. A multilayer structure suitable for forming part of an organic electronic device, said structure comprising at least one couple of layers L1 and L2 which are adjacent to each other, wherein
a. said layer L1 of the multilayer structure is an emissive layer and comprises at least 50 wt %, based on the total weight of L1, of a compound C1 selected from the group consisting of compounds of the formula SBF,′
b. said layer L2 of the multilayer structure comprises at least 50 wt %, based on the total weight of L2, of a compound C2, which may be the same or different from C1, selected from the group consisting of compounds of the formula SBF,
wherein
each SBF represents a substituted or unsubstituted spirobifluorene of formula (1) or a substituted or unsubstituted open spirobifluorene of formula (2), 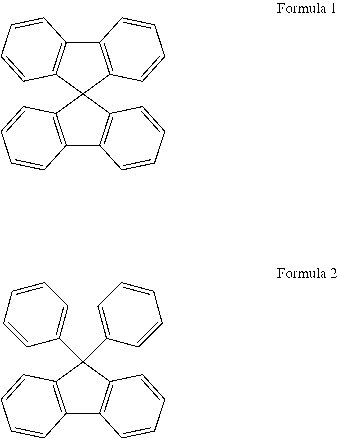
wherein compound C1 and compound C2 comprise the same total number of units chosen from SBF, and
wherein the HOMO and LUMO levels of the compound C1 are the same as, or differ by at most 0.2 eV from, respectively, the HOMO and LUMO levels of the organic compound C2, as measured by cyclic voltammetry in solution.

2. A multilayer structure suitable for forming part of an organic electronic device, said structure comprising at least one couple of layers L1 and L2 which are adjacent to each other, wherein
a. said layer L1 of the multilayer structure comprises at least 50 wt %, based on the total weight of L1, of a compound C1 selected from the group consisting of compounds of the formulae SBF′-Lnk-SBF′ or SBF′-Lnk-(-SBF″-Lnk′-)ₙ-SBF′
b. said layer L2 of the multilayer structure comprises at least 50 wt %, based on the total weight of L2, of a compound C2, which may be the same or different from C1, selected from the group consisting of compounds of the formulae SBF′-Lnk-SBF′ or SBF′-Lnk-(-SBF″-Lnk′-)ₙ-SBF′,
wherein
n is an integer of from 1 to 9,
each SBF′, which may be the same or different at each occurrence, represents a substituted or unsubstituted spirobifluorenyl of formula (1′) or a substituted or unsubstituted open spirobifluorenyl of formula (2′), wherein the solid lines represent the bond to the linker Lnk and the linker Lnk can be attached to any position of any of the aromatic rings 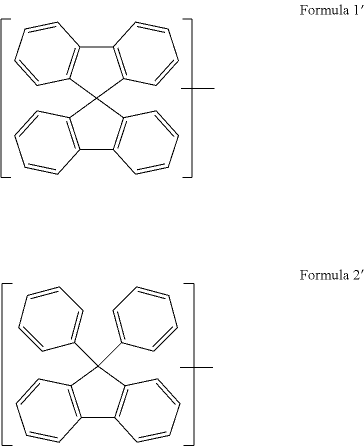
each SBF″, which may be the same or different at each occurrence, represents a substituted or unsubstituted spirobifluorenylene of formula (1″) or a substituted or unsubstituted open spirobifluorenylene of formula (2″) 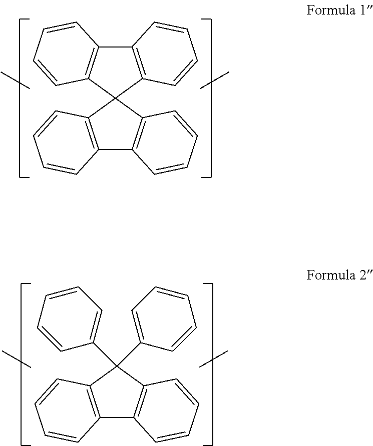
wherein the solid lines represent the bonds to the linker Lnk respectively Lnk′ and Lnk and Lnk′ may be attached to any position of any of the aromatic rings,
compound C1 and compound C2 comprise the same total number of units chosen from SBF′ and SBF″ units
and
wherein the HOMO and LUMO levels of the compound C1 are the same as, or differ by at most 0.2 eV from, respectively, the HOMO and LUMO levels of the organic compound C2, as measured by cyclic voltammetry in solution.

3. The multilayer structure in accordance with claim 2 wherein at least one of the SBF′ and SBF″ units in compounds C1 and C2 has at least one substituent other than hydrogen.

4. The multilayer structure in accordance with any of claim 1 wherein compounds C1 and C2 are identical.

5. The multilayer structure in accordance with claim 2 wherein Lnk and Lnk′, which may be the same or different at each occurrence, are a single bond, a C₁-C₃₀ hydrocarbylene or a C₁-C₃₀ heterohydrocarbylene.

6. The multilayer structure in accordance with claim 5 wherein Lnk and Lnk′, which may be the same or different at each occurrence, are selected from divalent residues of biphenyl or triphenyl or a divalent residue of the following formulae (3) to (10) 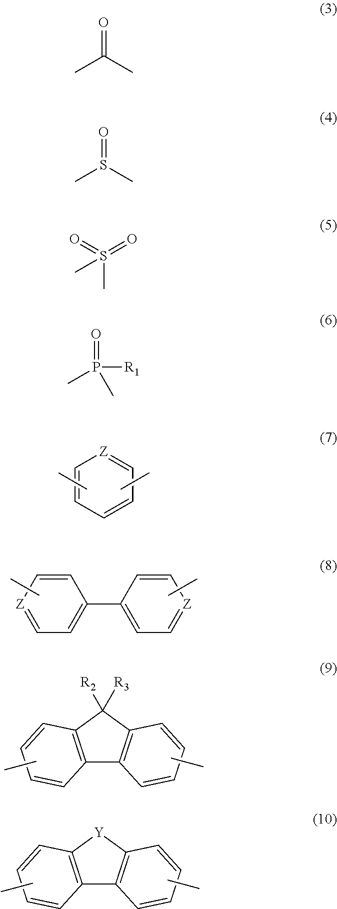
wherein Z is selected from C, N, O or S, Y is N—R₄, O, S or SiR₅R₆, wherein R₁ is selected from C₁-C₂₀ hydrocarbyl or C₁-C₂₀ heterohydrocarbyl, R₂ and R₃ are independently selected from hydrogen or C₁-C₂₀ alkyl, and R₄, R₅ and R₆ are independently selected from C₁-C₂₀ hydrocarbyl or C₁-C₂₀ heterohydrocarbyl, preferably from C₁-C₂₀ alkyl or C₁-C₂₀ aryl.

7. The multilayer structure in accordance with claim 2 wherein compounds C1 and C2 are independently selected from

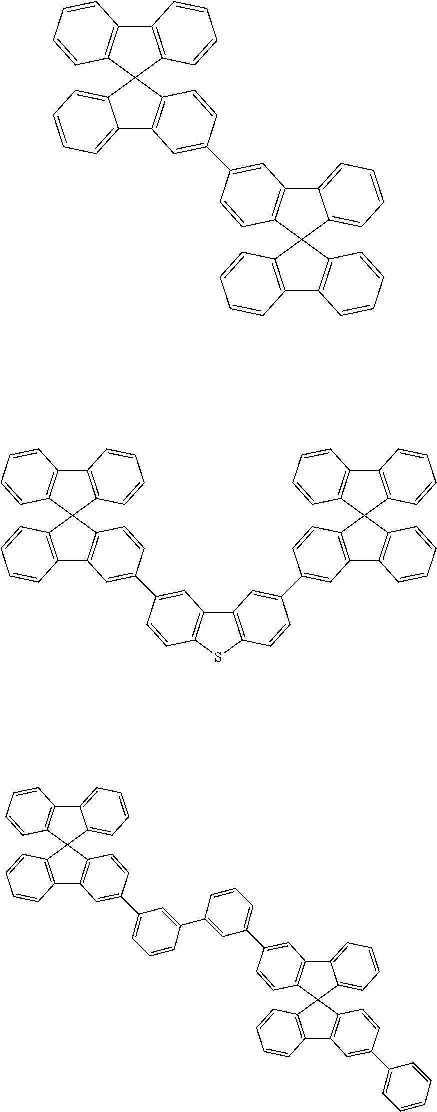

8. The multilayer structure in accordance with claim 1 wherein the SBF or open SBF is selected from compounds of formula 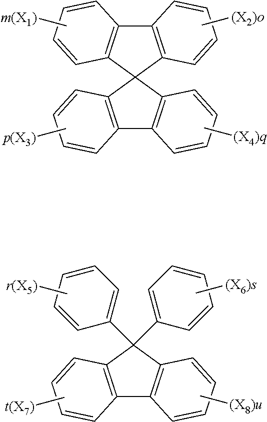
wherein X₁ to X₈ are independently selected from substituents other than hydrogen and m, o, p, q, r, s, t and u, independently of one another represent an integer of from 0 to 4.

9. The multilayer structure in accordance with claim 1 wherein C1 and C2 are independently selected from

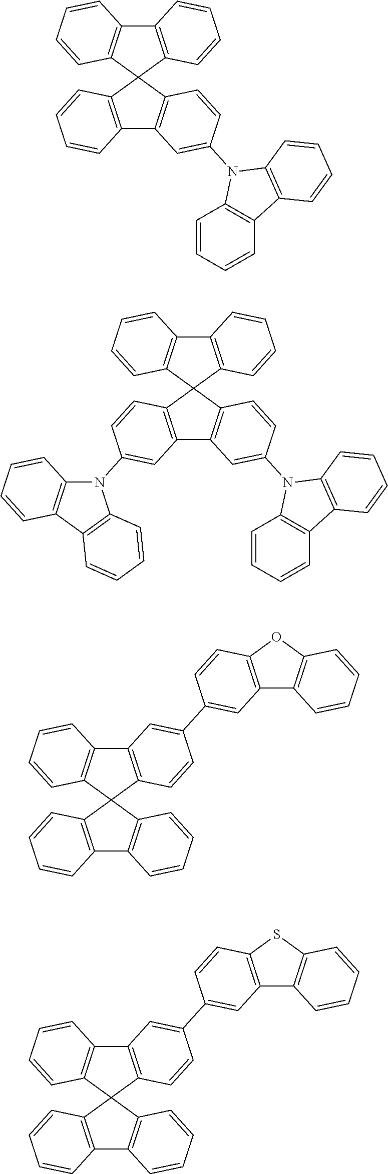

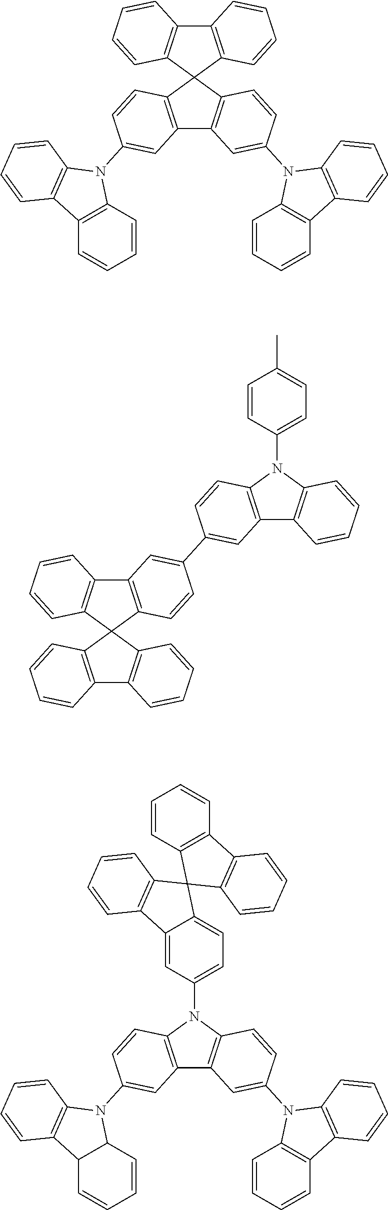 [SMILES: c1ccc2c(c1)-c1ccccc1C21c2ccc(-n3c4ccccc4c4ccccc43)cc2-c2cc(-n3c4ccccc4c4ccccc43)ccc21 ; Cc1ccc(-n2c3ccccc3c3cc(-c4ccc5c(c4)-c4ccccc4C54c5ccccc5-c5ccccc54)ccc32)cc1 ; C1=CC2c3ccccc3N(c3ccc4c(c3)c3cc(-n5c6ccccc6c6ccccc65)ccc3n4-c3ccc4c(c3)-c3ccccc3C43c4ccccc4-c4ccccc43)C2C=C1]

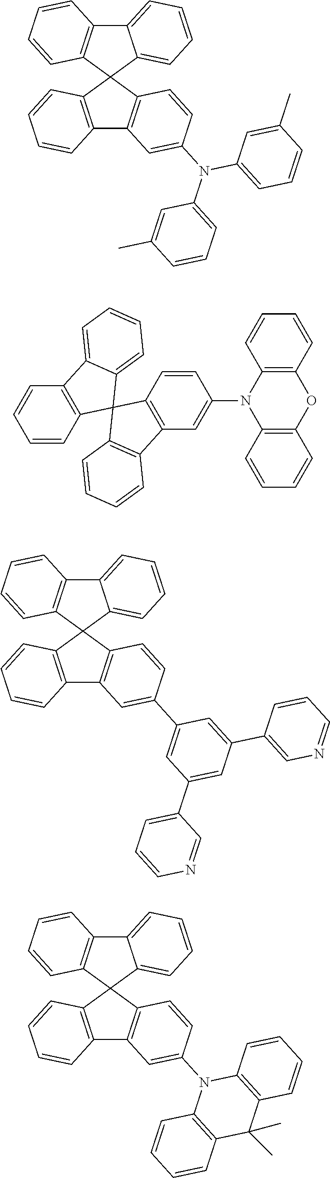

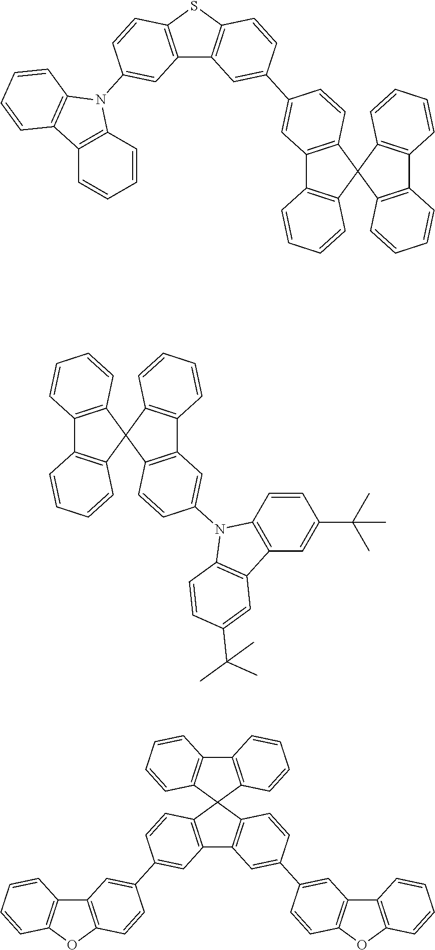 [SMILES: c1ccc2c(c1)-c1ccccc1C21c2ccccc2-c2cc(-c3ccc4sc5ccc(-n6c7ccccc7c7ccccc76)cc5c4c3)ccc21 ; CC(C)(C)c1ccc2c(c1)c1cc(C(C)(C)C)ccc1n2-c1ccc2c(c1)-c1ccccc1C21c2ccccc2-c2ccccc21 ; c1ccc2c(c1)-c1ccccc1C21c2ccc(-c3ccc4oc5ccccc5c4c3)cc2-c2cc(-c3ccc4oc5ccccc5c4c3)ccc21]

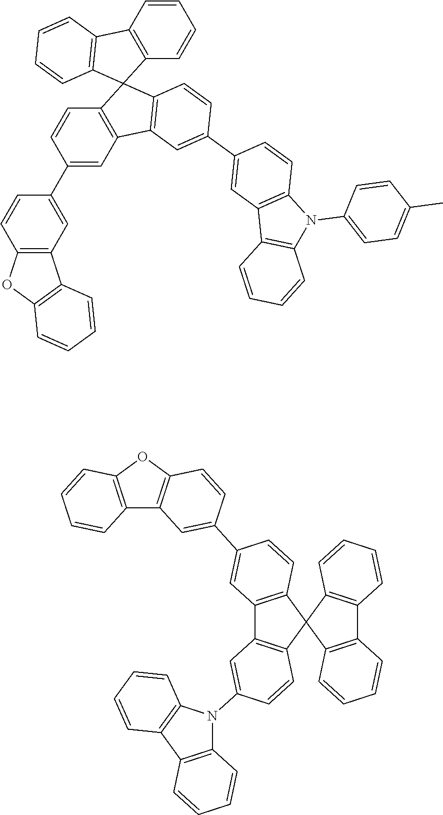 [SMILES: Cc1ccc(-n2c3ccccc3c3cc(-c4ccc5c(c4)-c4cc(-c6ccc7oc8ccccc8c7c6)ccc4C54c5ccccc5-c5ccccc54)ccc32)cc1 ; c1ccc2c(c1)-c1ccccc1C21c2ccc(-c3ccc4oc5ccccc5c4c3)cc2-c2cc(-n3c4ccccc4c4ccccc43)ccc21]

10. The multilayer structure in accordance with claim 1, said structure comprising at least one triplet of layers L1, L2 and L3, wherein layers L1 and L2 are as specified, wherein layers L2 and L3 are adjacent to each other, and wherein said layer L3 comprises at least 50 wt %, based on the total weight of L3, of a compound C3 which may be the same or different from C1 and C2, selected from the group consisting of compounds of the formulae SBF, SBF′-Lnk-SBF′ or SBF′-Lnk-(-SBF″-Lnk′-)ₙ-SBF′, wherein n is an integer of from 1 to 9.

11. The multilayer structure in accordance with claim 10, said structure comprising at least one quadruplet of layers L1, L2, L3 and L4 wherein layers L3 and L4 are adjacent to each other, and wherein said layer L4 comprises at least 50 wt %, based on the total weight of L4, of a compound C4 which may be the same or different from C1, C2 or C3, selected from the group consisting of compounds of the formulae SBF, SBF′-Lnk-SBF′ or SBF′-Lnk-(-SBF″-Lnk′-)ₙ-SBF′, wherein n is an integer of from 1 to 9.

12. The multilayer structure in accordance with claim 11, said structure comprising at least one quintuplet of layers L1, L2, L3, L4 and L5 wherein layers L4 and L5 are adjacent to each other, and wherein said layer L5 comprises at least 50 wt %, based on the total weight of L5, of a compound C5 which may be the same or different from C1, C2, C3 or C4, selected from the group consisting of compounds of the formulae SBF, SBF′-Lnk-SBF′ or SBF-Lnk-(-SBF″-Lnk′-)ₙ-SBF′, wherein n is an integer of from 1 to 9.

13. An organic electronic device comprising the multilayer structure in accordance with claim 1.

14. The organic electronic device in accordance with claim 13 which is an organic light-emitting diode.

15. The organic electronic device in accordance with claim 13, comprising an electron transport layer and an emissive layer, wherein layer L1 is the emissive layer and layer L2 is the electron transport layer.

16. An organic electronic device which is an organic light-emitting diode comprising the multilayer structure in accordance with claim 10, said organic light-emitting diode comprising an electron injection layer, an electron transport layer and an emissive layer, wherein layer L1 is the electron injection layer, layer L2 is the electron transport layer and layer L3 is the emissive layer.

17. An organic electronic device which is an organic light-emitting diode comprising the multilayer structure in accordance with claim 11, said organic light-emitting diode comprising an electron injection layer, an electron transport layer, an emissive layer and a hole transporting layer, wherein layer L1 is the electron injection layer, layer L2 is the electron transport layer, layer L3 is the emissive layer and layer L4 is the hole transporting layer.

18. An organic electronic device which is an organic light-emitting diode comprising the multilayer structure in accordance with claim 12, said organic light-emitting diode comprising an electron injection layer, an electron transport layer, an emissive layer, a hole transporting layer and a hole injection layer, wherein layer L1 is the electron injection layer, layer L2 is the electron transport layer, layer L3 is the emissive layer, layer L4 is the hole transporting layer and layer L5 is the hole injection layer.

19. The multilayer structure in accordance with claim 2 wherein compounds C1 and C2 are identical.

20. The multilayer structure in accordance with claim 2, said structure comprising at least one triplet of layers L1, L2 and L3, wherein layers L1 and L2 are as specified, wherein layers L2 and L3 are adjacent to each other, and wherein said layer L3 comprises at least 50 wt %, based on the total weight of L3, of a compound C3 which may be the same or different from C1 and C2, selected from the group consisting of compounds of the formulae SBF, SBF′-Lnk-SBF′ or SBF′-Lnk-(-SBF″-Lnk′-)ₙ-SBF′, wherein n is an integer of from 1 to 9.
